(19) United States
(12) Patent Application Publication
(10) Pub. No.: US 2010/0005647 A1
(43) Pub. Date: Jan. 14, 2010

(54) METHOD OF MANUFACTURING AN INLET MEMBER FOR AN ELECTRONIC TAG

(75) Inventors: Yuichi MORINAGA, Tokyo (JP); Yuji IKEDA, Tokyo (JP); Shintaro SAKAMOTO, Tokyo (JP)

Correspondence Address: MATTINGLY & MALUR, P.C., 1800 DIAGONAL ROAD, SUITE 370, ALEXANDRIA, VA, 22314, US

(73) Assignee: Renesas Technology Corp., Tokyo (JP)

(21) Appl. No.: 12/558,915

(22) Filed: Sep. 14, 2009

Related U.S. Application Data
(63) Continuation of application No. 10/592,477, filed on Sep. 11, 2006.

(30) Foreign Application Priority Data
Mar. 12, 2004 (JP) 2004-70463

(51) Int. Cl. H01P 11/00; H05K 3/30

(52) U.S. Cl. 29/600; 29/601; 29/832

(57) ABSTRACT

In order to offer the technology which can form the pattern of the antenna of the inlet for electronic tags accurately and cheaply, the resist layer at the time of forming the pattern of an antenna by chemical etching is formed using a photogravure printing machine. Let the extending direction of region 16C which has the minimum width in the height of the front surface of a gravure plate be an opposite direction to the direction of rotation of a gravure plate (a doctor's relative direction of movement seen from the gravure plate). The radius of curvature of an inner circumference of the curved part in region 16B is made larger than the radius of curvature of a periphery. The outer edge of region 16D is formed so that it may become forward tapered shape-like toward position D, so that the width of region 16D may become larger than the width of region 16C in position D which the end of height attains.

### INCORPORATION BY REFERENCE

This application is a continuation application of U.S. Ser. No. 10/592,477, filed Sep. 22, 2006. The present application claims priority from PCT application PCT/JP2005/000467 filed on Jan. 17, 2005. The contents of all of the above-identified applications are hereby incorporated by reference.

### TECHNICAL FIELD

The present invention relates to a manufacturing technology of an inlet for noncontact type electronic tags, and particularly relates to an effective technology in the application to a patterning step of an antenna.

### BACKGROUND ART

For example, in when using conductor ink and forming the circuit pattern comprising a thin wire wiring part by a gravure method on a base material, there is technology which can form cheaply the circuit pattern comprising a thin wire wiring part by forming a printing plate with a direct printing method, forming the machine plate which surface-mounted the pattern of the thin wire wiring part to perpendicular direction or oblique direction to the doctor's direction, and doing gravure of the resist pattern of the circuit pattern comprising a thin wire wiring part on a work piece using this plate (for example, refer to Patent Reference 1).
[Patent Reference 1] Japanese Unexamined Patent Publication No.

### DISCLOSURE OF THE INVENTION

A noncontact type electronic tag is a tag which makes the memory circuit in a semiconductor chip memorize desired data, and reads this data using microwave, and has the structure which mounted the semiconductor chip in the antenna formed from a lead frame.

Since an electronic tag makes the memory circuit in a semiconductor chip memorize data, it has the advantage that mass data is memorizable compared with the tag using a bar code etc. There is also an advantage that an unjust alteration is difficult for the data which the memory circuit was made to memorize compared with the data which the bar code was made to memorize.

However, since structure is complicated compared with the tag using a bar code etc., the manufacturing cost of this kind of electronic tag is high, and this constitutes a cause which bars the spread of electronic tags. Present inventors are advancing analyses especially paying attention to the manufacturing process of an antenna. In an example of the manufacturing process of the antenna which present inventors examined, the pattern of an antenna is formed by doing chemical etching (wet etching) of the copper foil stuck on the base material of polyimide resin with adhesives by using as a mask the resist layer patterned by photo lithography technology. This technology has the problem that process cost is high, from the material cost of polyimide resin and copper being high, and TAT (Turn Around Time) which patterning of a resist layer takes becoming long.

Then, the present inventors examined the technology which forms the pattern of an antenna by using PEN (polyethylene naphthalate) or PET (polyethylene terephthalate) as a base material, sticking an aluminum foil on this base material with adhesives, transferring the pattern of a resist layer of the same plane form as the pattern of an antenna by a gravure method on the aluminum foil, and doing chemical etching by using the resist layer as a mask. According to this technology, since PEN and PET are cheap compared with polyimide resin and the aluminum foil is cheaper than a copper foil, reduction of material cost is expectable. The gravure method can transfer the pattern of a resist layer by short TAT from the ability of an exposure process, a developing process, etc. to be skipped as compared with photo lithography technology, and can expect reduction of process cost. However, present inventors found out the problem that the trench between patterns will be buried or will spread too much since the pattern formed becomes coarse compared with photo lithography technology when a gravure method is used.

A purpose of the present invention is to offer the technology which can form the pattern of the antenna of the inlet for electronic tags accurately and cheaply.

The above-described and the other purposes and novel features of the present invention will become apparent from the description herein and accompanying drawings.

Of the inventions disclosed in the present application, typical ones will next be summarized briefly.

The present invention is a manufacturing method of an inlet for electronic tags having an antenna which includes a conductor film formed over a main surface of an insulating film, a slit which is formed in a part of the antenna, and whose end extends and exists to an outer edge of the antenna, a semiconductor chip electrically connected to the antenna via a plurality of bump electrodes, and resin which seals the semiconductor chip, comprising the steps of:

(a) preparing the insulating film with which the conductor film was formed over the main surface;

(b) forming a masking pattern of a form corresponding to a concave pattern over the conductor film by a gravure method using a gravure plate in which the concave pattern corresponding to the antenna and a convex pattern corresponding to the slit were formed, and a doctor blade; and

(c) forming the antenna which has the slit, etching the conductor film by using the masking pattern as a mask;

wherein

the convex pattern includes a first region which extends and exists to a first direction which is a relative direction of movement of a doctor blade, and has a minimum, first width in the convex pattern, a second region which has one or more curved parts, and a third region extending and existing to a second direction which intersects the first direction; and

in the curved part, a first radius of curvature of a first outer edge located inside relatively is larger than a second radius of curvature of a second outer edge located outside relatively.

The present invention is a manufacturing method of an inlet for electronic tags having an antenna which includes a conductor film formed over a main surface of an insulating film, a slit which is formed in a part of the antenna, and whose end extends and exists to an outer edge of the antenna, a semiconductor chip electrically connected to the antenna via a plurality of bump electrodes, and resin which seals the semiconductor chip, comprising the steps of:

(a) preparing the insulating film with which the conductor film was formed over the main surface;

(b) forming a masking pattern of a form corresponding to a concave pattern over the conductor film by a gravure method using a gravure plate in which the concave pattern corresponding to the antenna and a convex pattern corresponding to the slit were formed, and a doctor blade; and

(c) forming the antenna which has the slit, etching the conductor film by using the masking pattern as a mask;

wherein

the convex pattern includes a first region which extends and exists to a first direction which is a relative direction of movement of a doctor blade, and has a minimum, first width in the convex pattern, a second region which has one or more curved parts, a third region extending and existing to a second direction which intersects the first direction, and a fourth region whose portion overlaps the first region, and which extends and exists in the first direction, and arrives at a first position corresponding to the outer edge of the antenna in the concave pattern; and

a second width in the first position of the fourth region is larger than the first width.

The present invention is a manufacturing method of an inlet for electronic tags having an antenna which includes a conductor film formed over a main surface of an insulating film, a slit which is formed in a part of the antenna, and whose end extends and exists to an outer edge of the antenna, a semiconductor chip electrically connected to the antenna via a plurality of bump electrodes, and resin which seals the semiconductor chip, comprising the steps of:

(a) preparing the insulating film with which the conductor film was formed over the main surface;

(b) forming a masking pattern of a form corresponding to a concave pattern over the conductor film by a gravure method using a gravure plate in which the concave pattern corresponding to the antenna and a convex pattern corresponding to the slit were formed, and a doctor blade; and

(c) forming the antenna which has the slit, etching the conductor film by using the masking pattern as a mask;

wherein

the convex pattern includes a first region which extends and exists to a first direction which is a relative direction of movement of a doctor blade, and has a minimum, first width in the convex pattern, a second region which has one or more curved parts, and a third region extending and existing to a second direction which intersects the first direction; and

the first width is less than or equal to 150 μm.

Advantages achieved by some of the most typical aspects of the invention disclosed in the present application will be briefly described below.

That is, the pattern of the antenna of the inlet for electronic tags can be formed accurately and cheaply.

### BRIEF DESCRIPTION OF THE DRAWINGS

FIG. 1 is a plan view showing a part of long insulating films used for manufacture of the inlet for electronic tags which is the 1 embodiment of the present invention;

FIG. 2 is a plan view expanding and showing a part of insulating films shown in FIG. 1;

FIG. 3 is a plan view expanding and showing a part of antennas formed in one side of the insulating film shown in FIG. 1 and FIG. 2;

FIG. 4 is a plan view of the semiconductor chip mounted in the inlet for electronic tags which is the 1 embodiment of the present invention;

FIG. 5 is a principal part cross-sectional view at the time of mounting the semiconductor chip shown in FIG. 4 on an insulating film;

FIG. 6 is an explanatory diagram of the photogravure printing machine used for manufacture of the inlet for electronic tags which is the 1 embodiment of the present invention;

FIGS. 7 and 8 are explanatory diagrams showing the principal part of the front surface of the gravure plate included in the photogravure printing machine shown in FIG. 6;

FIG. 9 is a schematic diagram of a bonder showing a part of manufacturing process (connection step of a semiconductor chip and an antenna) of the inlet for electronic tags which is the 1 embodiment of the present invention;

FIG. 10 is a cross-sectional view of the bump electrode formed on the main surface of the semiconductor chip shown in FIG. 4, and its neighborhood;

FIG. 11 is a cross-sectional view of the dummy bump electrode formed on the main surface of the semiconductor chip shown in FIG. 4, and its neighborhood;

FIG. 12 is a schematic diagram expanding and showing the principal part of the bonder shown in FIG. 9;

FIG. 13 is a schematic diagram showing a part of manufacturing process (resin seal step of a semiconductor chip) of the inlet for electronic tags which is the 1 embodiment of the present invention;

FIG. 14 is a block diagram of the circuit formed in the main surface of the semiconductor chip shown in FIG. 4;

FIG. 15 is a side view showing the inlet for electronic tags which is the 1 embodiment of the present invention;

FIG. 16 is a side view showing the state where the insulating film used for manufacture of the inlet for electronic tags which is the 1 embodiment of the present invention was rolled round to the reel;

FIG. 17 is a plan view (front surface side) showing the inlet for electronic tags which is the 1 embodiment of the present invention; and

FIG. 18 is an explanatory diagram showing the manner of use of the electronic tag using the inlet for electronic tags which is the 1 embodiment of the present invention.

### BEST MODE FOR CARRYING OUT THE INVENTION

Hereafter, embodiments of the invention are explained in detail based on drawings. In all the drawings for describing the embodiments, members of the same function will be identified by the same reference numerals in principle and overlapping descriptions will be omitted.

The inlet for electronic tags of this embodiment (it is only hereafter described as an inlet) forms the main part of the noncontact type electronic tag provided with the antenna for microwave reception.

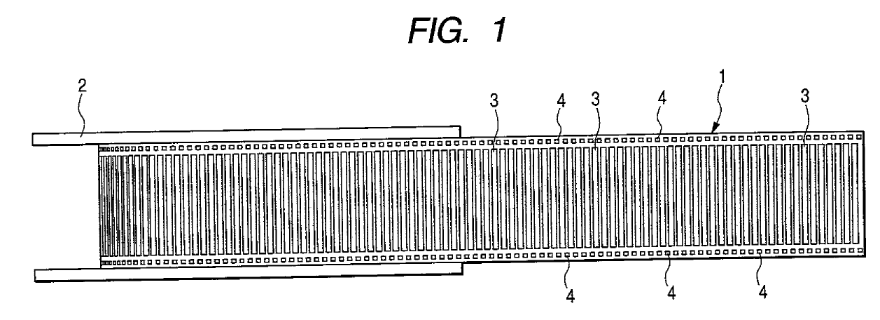

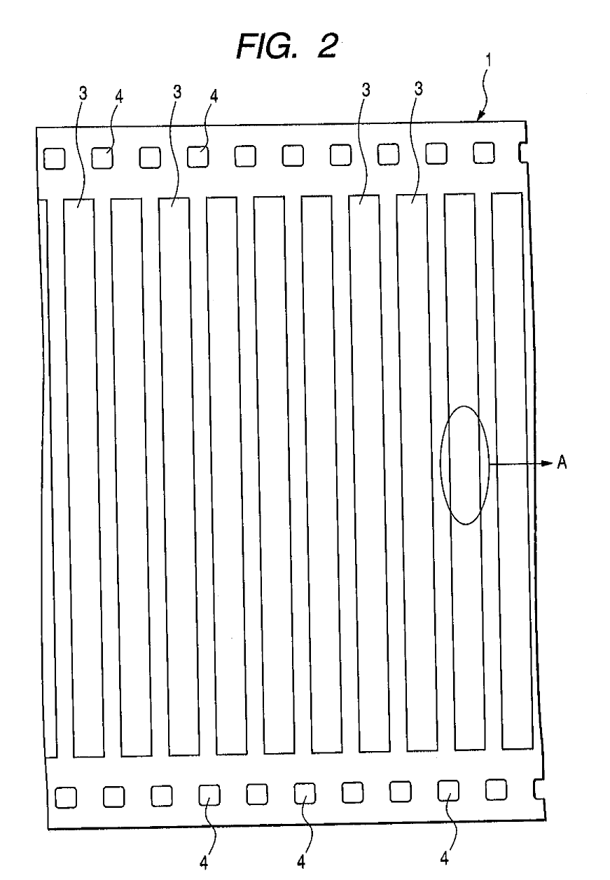

FIG. 1 is a plan view showing insulating film 1 used for manufacture of the inlet of this embodiment, and FIG. 2 is a plan view expanding and showing an part of FIG. 1.

As shown in FIG. 1 and FIG. 2, insulating film 1 is carried in to the manufacturing process of the inlet of this embodiment after having been rolled round by reel 2. Many antennas 3 are beforehand formed in one side of this insulating film 1 at the predetermined gap. In this embodiment, insulating film 1 is formed, for example of PEN or PET. Antenna 3 is formed, for example of Al (aluminum) film (conductor film). Thus, the material cost of an inlet can be reduced by using Al as a material of antenna 3, using PEN or PET as a material of insulating film 1 compared with the case where for example, Cu (copper) is used as a material of antenna 3 using polyimide resin as a material of insulating film 1.

The above-mentioned insulating film 1 is a thing in alignment with the standard of the film carrier tape, it is formed, for example by width about 48 mm or about 70 mm, and a thickness about 50 μm, and sprocket holes 4 for transporting insulating film 1 are formed in both side parts at the predetermined gap. This sprocket hole 4 can be formed by punching a part of insulating films 1 by punch, for example.

The length of the long side direction of the above-mentioned antenna 3 is about 51 mm, for example, and it is optimized so that microwave with a frequency of 2.45 GHz can be received efficiently. The width of antenna 3 is about 1.5 mm, and it is optimized so that the miniaturization of an inlet and strength reservation can be compatible.

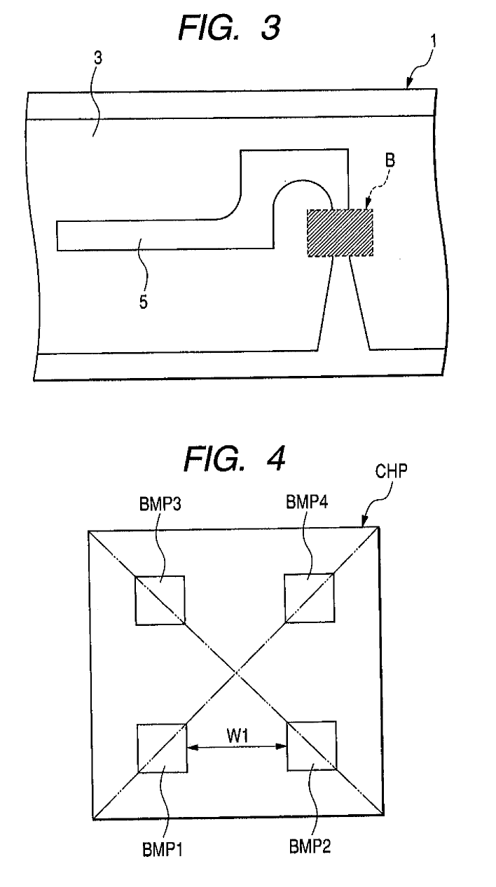

FIG. 3 is a plan view expanding and showing the region shown by A (almost central part of antenna 3) in FIG. 2. As shown in FIG. 3, slit 5 whose end arrives at the outer edge of antenna 3 is formed in the almost central part of antenna 3. On the halfway part of this slit 5, region B where a semiconductor chip (it is only hereafter described as a chip) is mounted at a later step is formed. The width of slit 5 is the narrowest in the portion which overlaps this region B. Thereby becomes possible to prevent expansion of this region B, and it becomes possible to prevent enlargement of the chip mounted in region B.

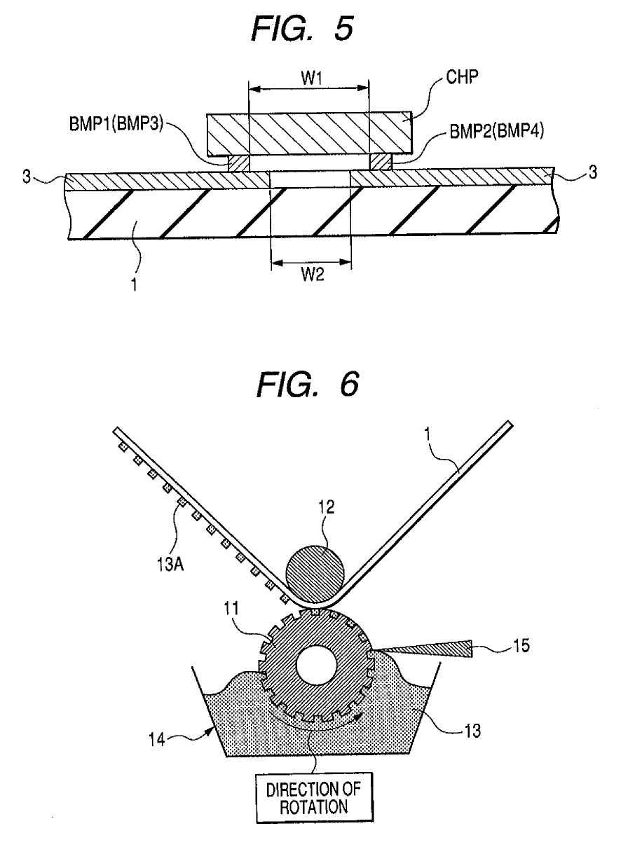

FIG. 4 is a plan view showing the layout of four bump electrodes BMP1-BMP4 formed in the main surface of chip CHP mounted in the above-mentioned region B, and FIG. 5 is a principal part cross-sectional view of insulating film 1 at the time of chip CHP being mounted in region B.

Chip CHP includes a single crystal silicon substrate of thickness about 0.1 mm, and the circuit which includes the rectification and transmission, clock extraction, a selector, a counter, ROM, etc. which are mentioned later is formed in the main surface. ROM has a storage capacity of 128 bits and can memorize mass data compared with storage media, such as a bar code. There is an advantage that an unjust alteration is difficult for the data which ROM was made to memorize compared with the data which the bar code was made to memorize.

On the main surface of chip CHP in which the above-mentioned circuit was formed, four bump electrodes BMP1-BMP4 which include Au(s) (gold), for example are formed. These four bump electrodes BMP1-BMP4 are arranged so that they may be located on the imagination diagonal line of the pair shown with the alternate long and two short dashes line of FIG. 4 and the distance from the intersection (the center of the main surface of chip CHP) of these diagonal lines may become almost equal. Balance can be made easy to maintain to the load at the time of connection of chip CHP by considering it as such a layout. These bump electrodes BMP1-BMP4 were formed, for example using the well-known electrolysis electroplating method, and the height is about 15 μm, for example. Distance W1 between adjoining bump electrodes (except for the contiguity on the same diagonal line) is 200 μm, for example. In order to keep bump electrodes BMP1-BMP4 from falling into slit 5 when such a chip CHP is mounted in the above-mentioned region B, it can be exemplified that the doubling margin of the connecting location of bump electrodes BMP1-BMP4 is made into about 25 μm for all directions on insulating film 1 (antenna 3), and width W2 (refer to FIG. 5) of slit 5 in region B is made less than or equal to about 150 μm at the maximum in this embodiment.

Next, the step which forms the above-mentioned antenna 3 is explained using FIG. 6-FIG. 8.

First, the Al foil about thickness 18 μm is adhered on one side of insulating film 1. Then, chemical etching (wet etching) of the Al foil is done to the form of antenna 3. In this embodiment, the pattern of the resist layer used as the mask at the time of this chemical etching is formed by the gravure method using a photogravure printing machine as shown in FIG. 6. This photogravure printing machine includes gravure plate 11 of which the irregularity corresponding to the pattern of a resist layer was formed in the front surface, presser-foot roll 12 which suppresses one side in which Al foil is pasted up of insulating film 1 on the front surface of gravure plate 11, resist resin liquid tub 14 holding resist resin liquid 13, doctor (doctor blade) 15, etc. Gravure plate 11 is formed by performing concave processing to the front surface, where for example, Cu (copper) is plated on the front surface of the material which includes Fe (iron) or Al, and plating Cr (chromium) further. Doctor 15 is the blade formed of thin steel. When gravure plate 11 rotates, resist resin liquid 13 adheres to the front surface of gravure plate 11, and fills the recess of the front surface. Subsequently, doctor 15 grinds the front surface of gravure plate 11, scratch and drop excessive resist resin liquid 13 of the front surface of gravure plate 11, and leaves resist resin liquid 13 to the recess. Furthermore, when gravure plate 11 rotates and insulating film 1 pressed down with presser-foot roll 12 and resist resin liquid 13 which remains in the recess of the front surface of gravure plate 11 touch, resist resin liquid 13 which remains in the recess is transferred to insulating film 1. This transferred resist resin liquid 13 constitutes resist layer (masking pattern) 13A used as the mask at the time of the above-mentioned chemical etching.

By forming the pattern of resist layer 13A using such a photogravure printing machine, an exposure process, a developing process, etc. can be skipped compared with the case of for example, forming the pattern of resist layer 13A by patterning using photolithography technology. Thereby, compared with the case where photolithography technology is used, it becomes possible to transfer the pattern of resist layer 13A to insulating film 1 by short TAT, and process cost can be reduced. Here, on one side in insulating film 1 at which Al foil is pasted up, the pattern of resist layer 13A is formed on the region used as antenna 3, and the pattern of resist layer 13A is not formed on the region used as slit 5. However, present inventors found out that the patterning accuracy of resist layer 13A may fall, and it may be in the state where resist layer 13A adhered on the region where the width of slit 5 becomes narrow being lower than or equal to about 150 μm, for example. When chemical etching of the Al foil is done by using such a resist layer 13A as a mask, we will be anxious about the generation of the trouble that slit 5 will break off on the way without removing Al foil in the region in which the width of slit 5 becomes narrow.

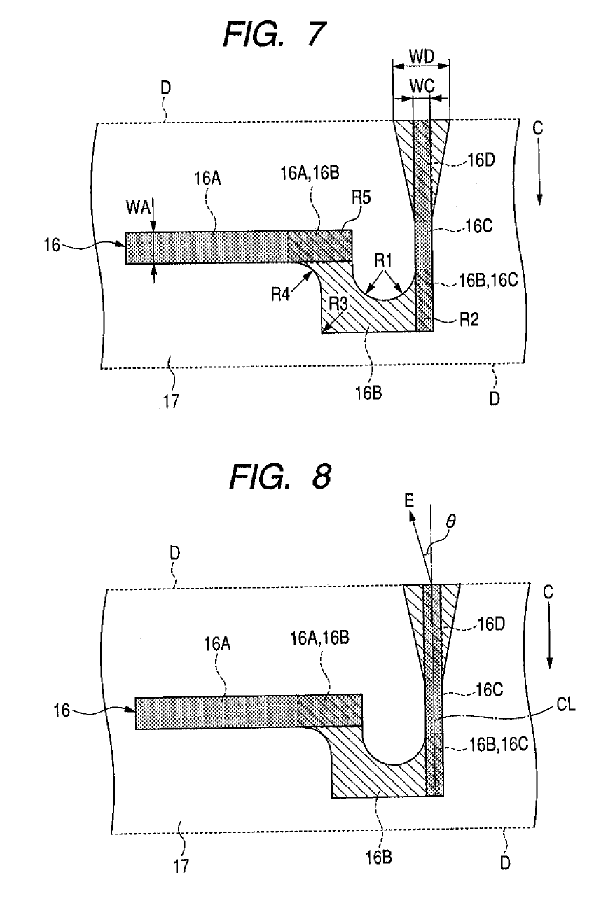

So, at this embodiment, the uneven part of the front surface of gravure plate 11 is formed by a design rule as shown in FIG. 7 and FIG. 8. Hereafter, this design rule is explained. FIG. 7 and FIG. 8 are the explanatory diagrams showing the principal part of the front surface of gravure plate 11, and show height 16 corresponding to one slit 5.

As shown in FIG. 7 and FIG. 8, the front surface of height (convex pattern) 16 constitutes form which reflected as mirror image the plane form of slit 5 (refer to FIG. 3). Height 16 includes region 16A (colored and illustrated in FIG. 7 and FIG. 8), region 16B (hatching of a slash is performed and illustrated in FIG. 7 and FIG. 8), region 16C (colored and illustrated in FIG. 7 and FIG. 8), and region 16D (hatching of a slash is performed and illustrated in FIG. 7 and FIG. 8), and each region includes the overlapping portion. The form of the portion which does not overlap regions 16B and 16D among regions (first region) 16C corresponds with the plane form of the portion of the slits 5 mentioned above which overlaps region B (refer to FIG. 3), and the width (width (first width) WC of region 16C) of height 16 constitutes the minimum in this portion. Such height 16 is surrounded by recess (concave pattern) 17 in the periphery, and regions 16C and 16D including the end of height 16 extends and exists to an opposite direction of direction of rotation C of gravure plate 11 (doctor's 15 (refer to FIG. 6) relative direction of movement seen from gravure plate 11 (the first direction)), and the end portion has arrived at position D corresponding to the outer edge of antenna 3. Region 16A extends and exists to the direction which intersects direction of rotation C of gravure plate 11, and region (second region) 16B has two or more curved parts (three places in the inside of FIG. 7 and FIG. 8).

According to the experiment which present inventors conducted, by making the extending direction of region 16C which has the minimum width WC in height 16 almost parallel to direction of rotation C of gravure plate 11 as mentioned above, when doctor 15 scratched and dropped excessive resist resin liquid 13 of the front surface of gravure plate 11 (refer to FIG. 6), it was able to prevent successfully resist resin liquid 13 remaining in a front surface also in region 16C in height 16 where width is the narrowest. Namely, even if it does chemical etching of the Al foil adhered on one side of insulating film 1 using resist layer 13A formed by transferring resist resin liquid 13 from gravure plate 11 to up to insulating film 1 as a mask, it becomes possible to remove surely the Al foil of the region where the width of slit 5 becomes narrow. As a result, it becomes possible to prevent slit 5 breaking off on the way.

In this embodiment, the radius of curvature (first radius of curvature) of an inner circumference (first outer edge) of the curved part in the above-mentioned region 16B is made larger than the radius of curvature (second radius of curvature) of a periphery (second outer edge). Namely, it is made for R4 to become larger than R5 in the curved part which makes R4 the radius of curvature of an inner circumference, and makes R5 the radius of curvature of a periphery, as shown in FIG. 7. It is made for R1 to become larger than R3 in the curved part which makes R1 the radius of curvature of an inner circumference, and makes R3 the radius of curvature of a periphery, and is made for R1 to become larger than R2 in the curved part which makes R1 the radius of curvature of an inner circumference, and makes R2 the radius of curvature of a periphery. Thereby, when doctor 15 scratches and drops excessive resist resin liquid 13 of the front surface of gravure plate 11 (refer to FIG. 6), change of the form of height 16 in the contact part of doctor 15 and gravure plate 11 can be made loose. Since a blot of resist resin liquid 13 can be suppressed as much as possible in R4 and the gap with R5 is wide, the phenomenon that resist resin liquid 13 will be connected in R4 and R5 by oozing out can be prevented. Even if resist resin liquid 13 oozes out at R3 and R2, since the gap with R1 is wide, the phenomenon that resist resin liquid 13 is connected can be prevented. Thereby, even if it does chemical etching of the Al foil adhered on one side of insulating film 1 using resist layer 13A which includes resist resin liquid 13 which was transferred from gravure plate 11 as a mask, it becomes possible to remove surely the Al foil of the region where the width of slit 5 becomes narrow. As a result, it becomes possible to prevent slit 5 breaking off on the way.

In this embodiment, so that width (second width) WD of region (fourth region) 16D may become larger than width WC of region 16C in position D (first position) which the end of height 16 attains, the outer edge of region 16D is formed so that it may become forward tapered shape-like toward position D. Here, the region on slit 5 and corresponding to region 16D does not overlap region B (refer to FIG. 3) where a chip is mounted. Therefore, since the width of slit 5 is widely securable in the region to which a chip is not arranged in the upper part by making width of region 16D larger than width WC of region 16C, a possibility that slit 5 will break off on the way when chemical etching of the Al foil adhered on one side of insulating film 1 is done can be made low. Since a curved part can be lost in region 16D by forming the outer edge of region 16D so that it may become forward tapered shape-like toward position D, in the outer edge of region 16D, the blot appearance of resist resin liquid 13 can be prevented, and it can prevent excessive resist resin liquid 13 remaining in the front surface of height 16.

Although the case where central line CL in the extending direction of region 16C, and doctor's 15 relative direction of movement E seen from gravure plate 11 became almost parallel was explained in this embodiment, in order to make resist pattern form good and to avoid the problem that slit 5 will break off, it is preferred to make a drift (angle θ) of the angle between central lines CL, and doctor's 15 direction of movement E at the maximum less than or equal to 15°. When the dimension error of a resist pattern shape is taken into consideration, the problem that slit 5 breaks off can be more surely prevented by making a drift of the angle less than or equal to 7°. According to the experiment which present inventors conducted, it was able to be prevented for excessive resist resin liquid 13 to remain on the front surface of height 16 also by setting up angle θ in this way. In particular, the good result was able to be obtained when width WC (width of slit 5 in region B (refer to FIG. 3)) of region 16C was less than about 150 μm. When above-mentioned central line CL and the above-mentioned direction of movement E are mostly in agreement on the other hand, and width WA of region (third region) 16A extending and existing in the direction (the second direction) which intersects perpendicularly with direction of movement E mostly was less than 150 μm, it turned out that excessive resist resin liquid 13 may remain on the front surface of height 16 on region 16A. Namely, by setting up the drift (angle θ) between the extending direction of region 16C which has the minimum width WC in height 16 (central line CL) and relative directions of movement E of doctor 15 which is seen from gravure plate 11 as mentioned above, it can be prevented surely for excessive resist resin liquid 13 to remain in the surface whole region of height 16. Even if it thereby does chemical etching of the Al foil adhered on one side of insulating film 1 by using as a mask resist layer 13A which includes resist resin liquid 13 which was transferred from gravure plate 11, it becomes possible to remove surely the Al foil of the region where the width of slit 5 becomes narrow. As a result, it becomes possible to prevent slit 5 breaking off on the way.

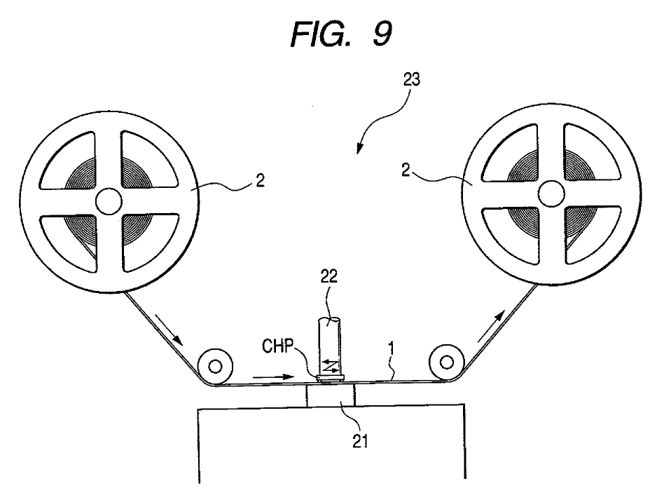

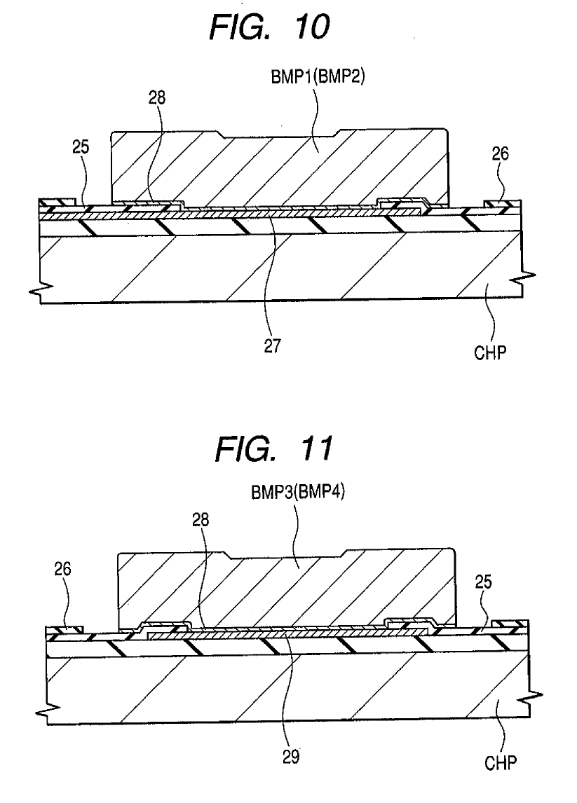

As shown in FIG. 9 after forming antenna 3 by the above means, chip CHP is connected to antenna 3, equipping bonder 23 provided with bonding stage 21 and ultrasonic bonding tool 22 with reel 2, and moving insulating film 1 along the upper surface of bonding stage 21. Here, FIG. 10 and FIG. 11 are the cross-sectional views of bump electrodes BMP1-BMP4 shown in FIG. 4, and the neighborhood of those. Bump electrode BMP1 forms the input terminal of the circuit mentioned later among bump electrodes BMP1-BMP4, and bump electrode BMP2 forms the GND terminal. Remaining two bump electrodes BMP3 and BMP4 form the dummy bumps which are not connected to the above-mentioned circuit. As shown in FIG. 10, bump electrode BMP1 which forms the input terminal of a circuit is formed on top layer metal wiring 27 to which passivation film 25 and polyimide resin film 26 which cover the main surface of chip CHP were etched and exposed. Between bump electrode BMP1 and top layer metal wiring 27, barrier metal film 28 for heightening both adhesion force is formed. Passivation film 25 includes a laminated film of a silicon oxide film and a silicon nitride film, for example, and top layer metal wiring 27 includes an aluminum alloy film, for example. Barrier metal film 28 includes for example, a laminated film of Ti film with high adhesion force over an aluminum alloy film, and Pd (palladium) film with high adhesion force over bump electrode BMP1. Although illustration is omitted, the connecting part of bump electrode BMP2 which forms the GND terminal of a circuit, and top layer metal wiring 27 also has the same structure as the above. On the other hand, as shown in FIG. 11, bump electrode BMP3 (and BMP4) which forms a dummy bump is connected to metal layer 29 formed in the same wiring layer as the above-mentioned top layer metal wiring 27, but this metal layer 29 is not connected to the circuit.

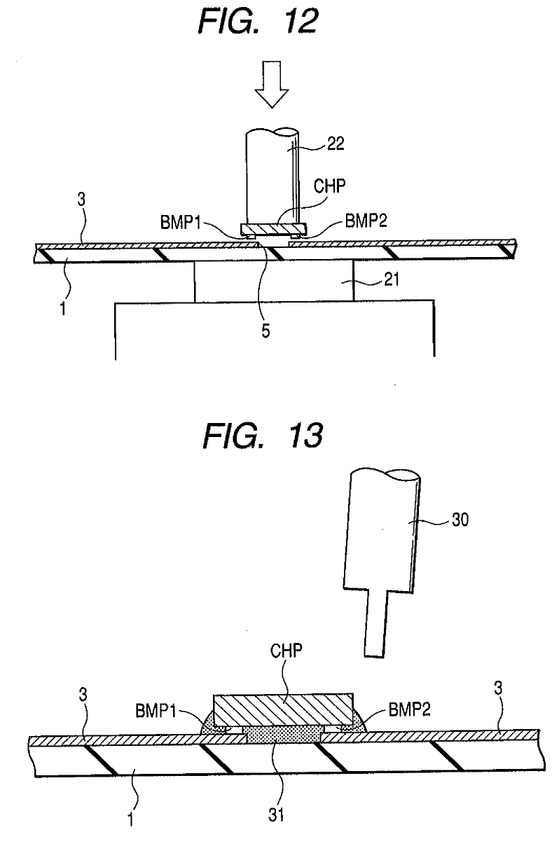

In order to connect chip CHP to antenna 3, as shown in FIG. 12 (principal part enlarged view of FIG. 9), antenna 3 is installed on bonding stage 21 heated to about 100° C., and chip CHP is mounted at the leading edge of ultrasonic bonding tool 22. Subsequently, after positioning chip CHP and antenna 3, chip CHP is pressed against the upper surface of antenna 3, and a bump electrode (BMP1-BMP4) and antenna 3 are contacted. At this time, by applying predetermined load and a predetermined ultrasonic wave to ultrasonic bonding tool 22 about 03.3 seconds, antenna 3 and a bump electrode (BMP1-BMP4) join together between metal at an interface, and a bump electrode (BMP1-BMP4) and antenna 3 adhere.

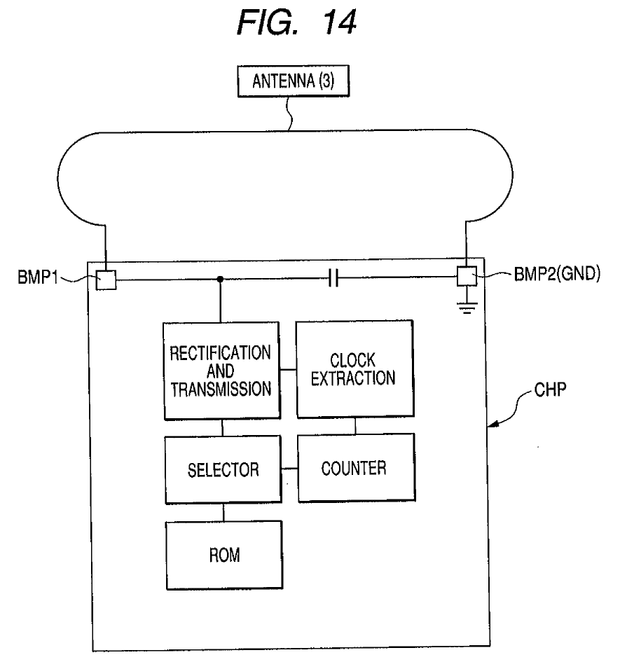

Here, FIG. 14 is a block diagram of the circuit formed in chip CHP (refer to FIG. 4). As mentioned above, the circuit which includes rectification and transmission, clock extraction, a selector, a counter, a ROM, etc. is formed in the main surface of chip CHP. As for the inlet of this embodiment, slit 5 whose end arrives at the outer edge of antenna 3 is formed in a part of antennas 3 formed in one side of insulating film 1. The input terminal (bump electrode BMP1) of chip CHP is connected to one side of antenna 3 divided into two by this slit 5, and the GND terminal (bump electrode BMP2) of chip CHP is connected to another side. The miniaturization of an inlet can be aimed at securing required antenna length by this structure, since the effectual length of antenna 3 can be lengthened.

Next, after mounting new chip CHP on bonding stage 21, and moving insulating film 1 by one pitch of antenna 3 continuously, this chip CHP is connected to antenna 3 by performing the same operation as the above. Henceforth, chip CHP is connected to all the antennas 3 formed in insulating film 1 by repeating the same operation as the above. Insulating film 1 to which the connection work of chip CHP and antenna 3 completed is transported to the following resin seal step after having been rolled round by reel 2.

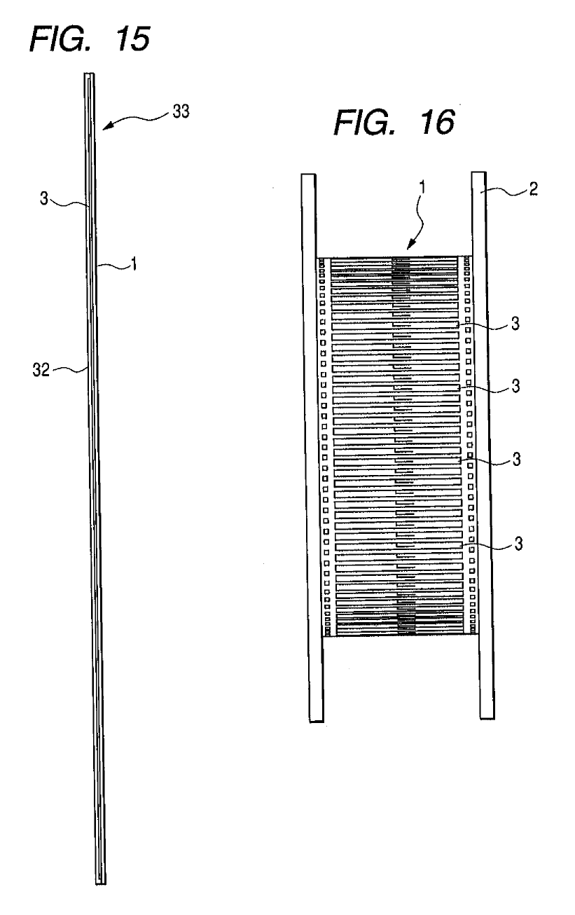

Next, as shown in FIG. 13, after filling up the clearance between the under surface of chip CHP, and insulating film 1 (and antenna 3) with under-filling resin 31 using dispenser 30 etc., this under-filling resin 31 is cured in a heating furnace. When curing under-filling resin 31 in a heating furnace, insulating film 1 which half-cures under-filling resin 31 first is rolled round to reel 2, next this reel 2 is carried in a heating furnace, and complete cure of the under-filling resin 31 is done. After half-curing under-filling resin 31, prior to the step which rolls round insulating film 1 to reel 2, inspection which judges the good or bad of connection of antenna 3 and chip CHP may be conducted. Since many antennas 3 formed in insulating film 1 have been electrically separated mutually, the continuity test of each antenna 3 and chip CHP can be carried out easily. Then, as shown in FIG. 15, the manufacturing process of inlet 33 of this embodiment is completed by laminating cover film 32 on the one side (surface in which antenna 3 was formed) of insulating film 1.

As shown in FIG. 16, inlet 33 manufactured as mentioned above is packed up after having been rolled round by reel 2, and is shipped to a customer.

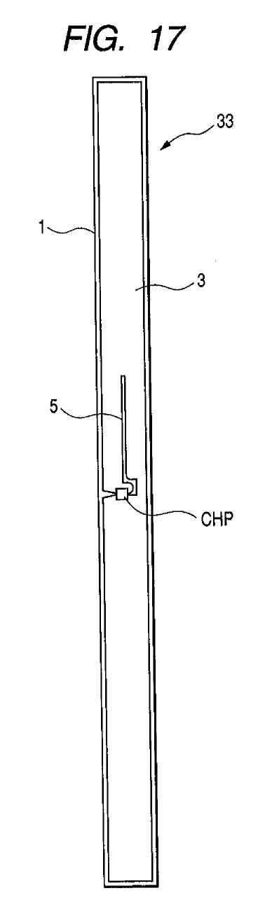

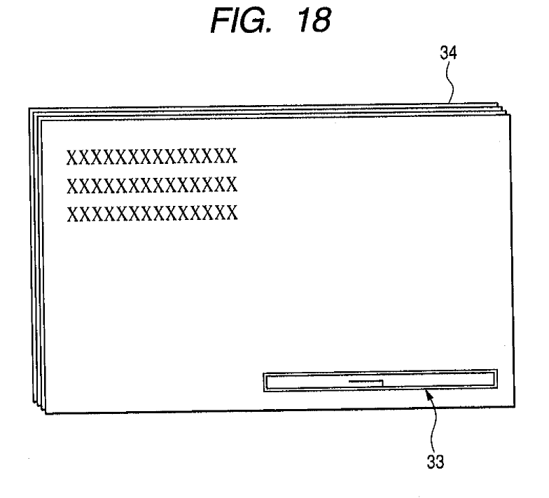

The customer who purchased the above-mentioned inlet 33 produces an electronic tag combining this inlet 33 and other members, after getting inlet 33 individually separated as shown in FIG. 17 by cutting insulating film 1. For example, FIG. 18 shows the example which stuck the double faced adhesive tape etc. on the back surface of inlet 33, produced the electronic tag and stuck this on the front surface of goods, such as check 34.

In the foregoing, the present invention accomplished by the present inventors is concretely explained based on above embodiments, but the present invention is not limited by the above embodiments, but variations and modifications may be made, of course, in various ways in the limit that does not deviate from the gist of the invention.

### INDUSTRIAL APPLICABILITY

The manufacturing method of the inlet for electronic tags of the present invention is applicable to the manufacturing process of the antenna in the inlet for electronic tags, for example.

1. A manufacturing method of an inlet for electronic tags having an insulating film, an antenna formed over a main surface of the insulating film, a slit formed in a part of the antenna, a semiconductor chip electrically connected to the antenna via a plurality of bump electrodes, and resin for sealing between the main surface of the antenna and the semiconductor chip, the slit extending to an outer edge of the antenna, the method comprising the steps of:
(a) providing the insulating film with the antenna;
(b) forming a masking pattern corresponding to a concave pattern of a gravure plate over the antenna by a gravure method using the gravure plate in which the concave pattern corresponding to the antenna and a convex pattern corresponding to the slit are formed in a side view;
(c) forming the antenna which has the slit by etching a conductor film by using the masking pattern as a mask; and
(d) mounting the semiconductor chip on the antenna via the plurality of bump electrodes such that the slit is arranged between the plurality of bump electrodes adjacent to each other;
wherein
the gravure plate is rotated in a first direction;
the convex pattern includes a first region extending to the first direction in a plan view, and a second region extending to a second direction intersecting with the first direction in a plan view;
a width of the second region is larger than that of first region;
the width of the first region is smaller than a distance between the plurality of bump electrodes of the semiconductor chip;
the slit has a first slit corresponding to the first region of the convex pattern and a second slit corresponding to the second region of the convex pattern;
the first slit has a first side and second side opposing to the first side;
the second slit has a third side and fourth side corresponding to the third side;
the first side of the first slit is arranged between the second side of the first slit and the third side of the second slit;
the slit has an inner circumference comprised of the first side of the first slit and the third side of the second slit, and an outer circumference comprised of the second side of the first slit and the fourth side of the second slit;
a curvature radius of the first circumference is larger than that of the second circumference; and
the semiconductor chip is mounted over the first slit.

2. A manufacturing method of an inlet for electronic tags according to claim 1, wherein
the slit is formed in a position corresponding to the first region and having a width such that the semiconductor chip can straddle the slit.

3. A manufacturing method of an inlet for electronic tags according to claim 1, wherein
the insulating film uses one of polyethylenenaphthalate and polyethylene terephthalate as a main ingredient.

4. A manufacturing method of an inlet for electronic tags according to claim 1, wherein
the conductor film uses aluminum as a main ingredient.

5. A manufacturing method of an inlet for electronic tags having an insulating film, an antenna formed over a main surface of the insulating film, a slit formed in a part of the antenna, a semiconductor chip electrically connected to the antenna via a plurality of bump electrodes, and resin for sealing between the main surface of the antenna and the semiconductor chip, the slit extending to an outer edge of the antenna, comprising the steps of:
(a) providing the insulating film with the antenna;
(b) forming a masking pattern corresponding to a concave pattern of a gravure plate over the antenna by a gravure method using the gravure plate in which the concave pattern corresponding to the antenna and a convex pattern corresponding to the slit were formed in a side view;
(c) forming the antenna which has the slit by etching a conductor film by using the masking pattern as a mask; and
(d) mounting the semiconductor chip on the antenna via the plurality of bump electrodes such that the slit is arranged between the plurality of bump electrodes adjacent to each other;
wherein
the gravure plate is rotated in a first direction;
the convex pattern includes a first region extending to the first direction in a plan view, a second region extending to a second direction intersecting with the first direction in a plan view, and a third region extending to the first direction in a plan view;
the third direction is arranged between the first region of the convex pattern and a part of the convex pattern corresponding to the outer edge of the antenna;
a width of the second region is larger than that of first region;
a width of the third region is larger than that of first region;
the width of the first region is smaller than a distance between the plurality of bump electrodes of the semiconductor chip;
the slit has a first slit corresponding to the first region of the convex pattern and a second slit corresponding to the second region of the convex pattern;
the first slit has a first side and second side opposing to the first side;
the second slit has a third side and forth side corresponding to the third side;
the first side of the first slit is arranged between the second side of the first slit and the third side of the second slit;
the slit has an inner circumference comprised of the first side of the first slit and the third side of the second slit, and outer circumference comprised of the second side of the first slit and the fourth side of the second slit; and
a curvature radius of the first circumference is larger than that of the second circumference; and
the semiconductor chip is mounted over the first slit.

6. A manufacturing method of an inlet for electronic tags according to claim 5, wherein
a width of the fourth region has a forward tapered shape form which becomes wider toward the first position.

7. A manufacturing method of an inlet for electronic tags according to claim 5, wherein
the slit is formed in a position corresponding to the first region and having a width such that the semiconductor chip can straddle the slit.

8. A manufacturing method of an inlet for electronic tags according to claim 5, wherein
the insulating film uses one of polyethylenenaphthalate and polyethylene terephthalate as a main ingredient.

9. A manufacturing method of an inlet for electronic tags according to claim 5, wherein
the conductor film uses aluminum as a main ingredient.
